(19) United States
(12) Patent Application Publication
(10) Pub. No.: US 2015/0060971 A1
(43) Pub. Date: Mar. 5, 2015

(54) NONVOLATILE SEMICONDUCTOR MEMORY DEVICE AND METHOD OF MANUFACTURING THE SAME

(71) Applicant: Kabushiki Kaisha Toshiba, Minato-ku (JP)

(72) Inventor: Yoshihisa FUJII, Yokkaichi-shi (JP)

(73) Assignee: Kabushiki Kaisha Toshiba, Minato-ku (JP)

(21) Appl. No.: 14/093,625

(22) Filed: Dec. 2, 2013

Related U.S. Application Data
(60) Provisional application No. 61/873,126, filed on Sep. 3, 2013.

(51) Int. Cl. H01L 27/115

(52) U.S. Cl. CPC H01L 27/11529; H01L 27/11534
USPC 257/300; 438/241

(57) ABSTRACT

According to one embodiment, a nonvolatile semiconductor memory device including a memory cell transistor having a stacked gate structure including a tunnel insulating film, a charge accumulation layer, a memory cell insulating film, and a control gate electrode film are orderly stacked above a semiconductor substrate, and a capacitor in which a first insulating film, a first electrode film, a second insulating film, a second electrode film, a third insulating film, and a third electrode film are orderly stacked above the semiconductor substrate is provided. A material of the second electrode film is same as the charge accumulation layer of the memory cell transistor. The third electrode film includes a material same as the control gate electrode film of the memory cell transistor.

### CROSS-REFERENCE TO RELATED APPLICATIONS

This application is based upon and claims the benefit of priority from U.S. Provisional Application No. 61/873,126, filed on Sep. 3, 2013; the entire contents of which are incorporated herein by reference.

### FIELD

Embodiments herein relate generally to a nonvolatile semiconductor memory device and a method of manufacturing the same.

### BACKGROUND

A NAND type flash memory has a plurality of memory cell transistors formed serially and having select gate transistors arranged on both sides thereof in a memory cell region of a semiconductor substrate, and peripheral circuit elements, configuring a control circuit to drive the memory cell transistors and the select gate transistors, are disposed in a peripheral circuit region. The peripheral circuit elements include a high voltage type field effect transistor (hereinbelow referred to as a high voltage type transistor), a low voltage type field effect transistor (hereinbelow referred to as a low voltage type transistor), and a capacitor, and the like.

The memory cell transistors have a structure in which a gate insulating film, a charge accumulation layer, an insulating film, and a control gate electrode film are stacked on the memory cell region of the semiconductor substrate. Further, the high voltage type transistor and the low voltage type transistor have a structure in which a gate insulating film and a gate electrode film are stacked on the peripheral circuit region of the semiconductor substrate. Further, the capacitor has a structure in which a lower layer electrode film, an insulating film, and an upper layer electrode film are stacked on the peripheral circuit region of the semiconductor substrate.

Generally, in order to simplify manufacturing steps, standardization of materials of the memory cell transistors and the peripheral circuit element is being performed in part. For example, conventionally, a floating gate electrode film of the memory cell transistors, the gate electrode film of the high voltage type transistor and the low voltage type transistor, and the lower layer electrode film of the capacitor are configured by the same material, an inter-electrode insulating film of the memory cell transistors and the insulating film of the capacitor are configured by the same material, and the control gate electrode film of the memory cell transistors and the upper layer electrode film of the capacitor are configured by the same material.

Now, in order to increase a capacitance per unit area, either a layout area of a capacitor is formed is increased, or a film thickness of the insulating film configuring the capacitor, that is, the inter-electrode insulating film, is to be thin. However, the increase in the layout area of the capacitor leads to increase a chip size, and further, thinning the film thickness of the inter-electrode insulating film may lead to a deterioration of reliability of the inter-electrode insulating film. Further, in the structure as above, a depletion layer may extend excessively when applying a voltage to the capacitor.

### BRIEF DESCRIPTION OF THE DRAWINGS

FIG. 1 is a cross sectional view illustrating an example of a structure of a nonvolatile semiconductor memory device of an embodiment;

FIG. 2 is one example of an example of an equivalent circuit diagram of a capacitor of the embodiment;

FIG. 3A is an example of a cross sectional view illustrating a structure of a capacitor provided in a general nonvolatile semiconductor memory device;

FIG. 3B is an example of an equivalent circuit diagram of the capacitor of FIG. 3A; and

FIG. 4 to FIG. 21 are diagrams illustrating an example of a procedure of a method of manufacturing the nonvolatile semiconductor memory device of the embodiment.

### DETAILED DESCRIPTION

In general, according to one embodiment, a nonvolatile semiconductor memory device including a memory cell transistor having a stacked gate structure including a tunnel insulating film, a charge accumulation layer, a memory cell insulating film, and a control gate electrode film are orderly stacked above a semiconductor substrate, and a capacitor in which a first insulating film, a first electrode film, a second insulating film, a second electrode film, a third insulating film, and a third electrode film are orderly stacked above the semiconductor substrate is provided. A material of the second electrode film is same as the charge accumulation layer of the memory cell transistor. The third electrode film includes a material same as the control gate electrode film of the memory cell transistor.

Hereinbelow, a nonvolatile semiconductor memory device and a method of manufacturing the same of an embodiment will be described in detail with reference to the attached drawings. Notably, the invention is not limited to the embodiment. Further, a cross sectional view of the nonvolatile semiconductor memory device used in the below embodiment is schematic, and there are cases in which a relationship of a thickness and a width of a layer, and a ratio of thicknesses of respective layers differ from actual implementations. Further, film thicknesses illustrated below are an example, and are not limited thereto.

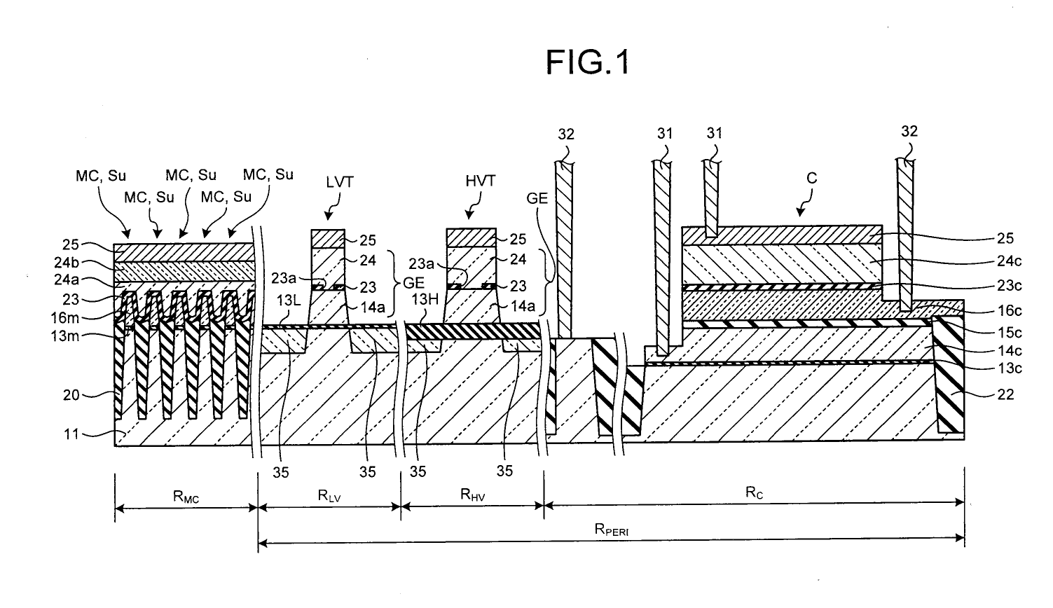

FIG. 1 is a cross sectional view illustrating an example of a structure of the nonvolatile semiconductor memory device of the embodiment. The nonvolatile semiconductor memory device includes memory cell transistors MC, and a peripheral circuit element for driving or controlling the memory cell transistors MC.

A memory cell region R_{MC} and a peripheral circuit region R_{PERI} are provided above a semiconductor substrate 11. A memory cell array disposed in the memory cell region R_{MC} includes two select gate transistors that are not illustrated, and a NAND cell unit (memory unit) Su configured of a memory cell string in which memory cell transistors MC are serially connected between these select gate transistors and the memory cell transistors MC are arranged in a matrix shape. In the NAND cell unit Su, the memory cell transistors MC are formed by sharing source/drain regions between those that are adjacent. In the drawing, a cross section in a direction vertical to an extended direction of the NAND cell unit Su is being illustrated.

The memory cell transistors MC in the memory cell region R_{MC} each have a stacked gate structure in which a tunnel insulating film 13m, a charge accumulation layer (for example, a floating gate electrode film) 16m, an inter-electrode insulating film 23, control gate electrode films 24a, 24b, and a metal electrode film 25 are orderly stacked above the semiconductor substrate 11 that is to be a channel, and the source/drain regions that are not illustrated and formed on surfaces on both sides of the semiconductor substrate 11 in the extended direction of the NAND cell unit Su of the stacked gate structure. The channel (surface of the semiconductor substrate 11) of the memory cell transistors MC that are adjacent in a direction intersecting the NAND cell unit Su, the tunnel insulating film 13m, and the floating gate electrode film 16m are isolated by element isolation insulating films 20 such as STI (Shallow Trench Isolation) formed at a predetermined interval. Further, the inter-electrode insulating film 23, the control gate electrode films 24a, 24b, and the metal electrode film 25 have a structure of being continuously formed between the memory cell transistors MC that are adjacent via the element isolation insulating films 20. Notably, positions of upper surfaces of the element isolation insulating films 20 are provided between an upper surface of the tunnel insulating film 13m and an upper surface of the floating gate electrode film 16m. Due to this, a structure in which the control gate electrode film 24a disposed on side surfaces of the floating gate electrode film 16m is formed, and it is possible to transmit a voltage applied to the control gate electrode films 24a, 24b efficiently to the floating gate electrode film 16m. Further, although not illustrated, the stacked gate structures that are adjacent in the extended direction of the NAND cell unit Su are isolated for example by an interlayer insulating film.

The peripheral circuit region R_{PERI} includes a low electric field transistor forming region (hereinbelow referred to as an LVT region) R_{LV} where a low electric field transistor LVT for driving the memory cell transistors MC and the select gate transistors, a high electric field transistor forming region (hereinbelow referred to as an HVT region) R_{HV} where a high electric field transistor HVT is formed, and a capacitor region R_{C} where a capacitor C is formed.

The low electric field transistor LVT in the LVT region R_{LV} includes a gate structure in which a gate insulating film 13L, a gate electrode layer GE, and a metal electrode film 25 are stacked above the semiconductor substrate 11, and source/drain regions 35 formed on the surfaces of the semiconductor substrate 11 on both sides in a gate longitudinal direction of the gate structure.

The high electric field transistor HVT in the HVT region R_{HV} includes a gate structure in which a gate insulating film 13H, a gate electrode layer GE, and a metal electrode film 25 are stacked above the semiconductor substrate 11, and source/drain regions 35 formed on the surfaces of the semiconductor substrate 11 on both sides in the gate longitudinal direction of the gate structure. Notably, the gate insulating film 13H is formed thick compared to the gate insulating film 13L of the low electric field transistor LVT, and the high electric field transistor HVT has a high voltage resistance compared to the low electric field transistor LVT.

The gate electrode layers GE of the low electric field transistor LVT and the high electric field transistor HVT each have a structure that a gate electrode film 14a, an inter-electrode insulating film 23, and a control gate electrode film 24 are stacked, and an opening 23a is formed in vicinity of a center of inter-electrode insulating film 23 and penetrates the inter-electrode insulating film 23 in a thickness direction so that an electric connection between the gate electrode film 14a and the control gate electrode film 24.

Further, in the HVT region R_{HV}, a step (trench) is provided so that the semiconductor substrate 11 becomes lowered by a predetermined depth compared to the upper surface of the semiconductor substrate 11 in the memory cell region R_{MC} and the LVT region R_{LV}. In the configuration of the nonvolatile semiconductor memory device illustrated in FIG. 1, the depth of the step is determined so that an upper surface of the metal electrode film 25 of the high electric field transistor HVT is equal to an upper surface of the metal electrode film 25 of the low electric field transistor LVT.

The capacitor C in the capacitor region R_{C} has a structure in which a first insulating film 13c, a first electrode film 14c, a second insulating film 15c, a second electrode film 16c, a third insulating film 23c, a third electrode film 24c, and a metal electrode film 25 are stacked in the semiconductor substrate 11 divided by element isolation insulating films 22. Further, first contacts 31 are connected to the first electrode film 14c and the metal electrode film 25 by penetrating an interlayer insulating film not illustrated so that the first electrode film 14c and the metal electrode film 25 (third electrode film 24c) become the same potential. Second contacts 32 are connected to the semiconductor substrate 11 and the second electrode film 16c by penetrating an interlayer insulating film not illustrated so that the semiconductor substrate 11 and the second electrode film 16c become the same potential. Here, the second contact 32 is disposed adjacent to the stacked structure via the element isolation insulating film 22. Further, the upper surface of the semiconductor substrate 11 in the regions where the second contact 32 is formed is at substantially equal to the upper surface of the semiconductor substrate 11 in the HVT region R_{HV}. That is, bottom surfaces of the second contact 32 are higher than a surface of the semiconductor substrate 11 in the region where the first electrode 14c of the capacitor C is formed.

Further, the first electrode film 14c is configured of the same material as the gate electrode films 14a of the low electric field transistor LVT and the high electric field transistor HVT, the second electrode film 16c is configured of the same material as the floating gate electrode films 16m of the memory cell transistors MC, the third insulating film 23c is configured of the same material as the inter-electrode insulating film 23 of the memory cell transistors MC, and the third electrode film 24c is configured of the same material as the control gate electrode films 24 of the low electric field transistor LVT and the high electric field transistor HVT.

Further, in the capacitor region R_{C}, a step (trench) is provided so that the semiconductor substrate 11 becomes lowered by a predetermined depth compared to the upper surface of the semiconductor substrate 11 in the memory cell region R_{MC} and the LVT region R_{LV}. In the configuration of the nonvolatile semiconductor memory device illustrated in FIG. 1, the depth of the step is determined so that the upper surface of the metal electrode film 25 of the capacitor C is equal to the upper surface of the metal electrode film 25 of the low electric field transistor LVT and the upper surface of the metal electrode film 25 of the high electric field transistor HVT. Notably, the step provided in the capacitor region R_{C} is formed deeper compared to the step provided in the HVT region R_{HV}.

Here, as the semiconductor substrate 11, a silicon substrate or an SOI (Silicon On Insulator) substrate and the like may be used. Notably, the region where the element is to be formed is preferably formed as a P type by doping with P type impurities such as Boron.

In the memory cell region R_{MC}, as the tunnel insulating films 13m, for example a silicon oxide film and the like with a thickness of 6 to 10 nm or so may be used. As the floating gate electrode films 16m, polycrystalline silicon films and the like having a thickness of 60 nm and with which P type impurities such as B are doped may be used. Further, the floating gate electrode films 16m may have a structure that contains a polycrystalline silicon film. For example, a stacked film of an insulating film and the polycrystalline silicon film may be used. As the inter-electrode insulating film 23, a silicon oxide film, a silicon nitride film, an ONO (Oxide-Nitride-Oxide) film having a stacked structure of the silicon oxide film and the silicon nitride film, a high dielectric film such as an aluminum oxide film or a hafnium oxide film, or a stacked structure of a low dielectric film such as a silicon oxide film or a silicon nitride film and the high dielectric film with a thickness of about 10 nm may be used. As the control gate electrode film 24a, for example a polycrystalline silicon film and the like having a thickness of 20 nm or so and with which P type impurities such as B are doped can be used, and as the control gate electrode film 24b, for example a polycrystalline silicon film having a thickness of 25 nm or so and with which no impurities are doped may be used. As the element isolation insulating films 20, polysilazane and the like may be used.

In the LVT region R_{LV} and the HVT region R_{HV}, as the gate insulating film 13L, for example a silicon oxide film with a thickness of 6 to 10 nm or so may be used, and as the gate insulating film 13H, for example a silicon oxide film with a thickness of 30 to 50 nm or so may be used. As the gate electrode films 14a, for example a polycrystalline silicon film and the like with a thickness of 80 nm or so and with which N type impurities such as P, As and the like are doped may be used. As the inter-electrode insulating films 23, a silicon oxide film, a silicon nitride film, an ONO film having a stacked structure of the silicon oxide film and the silicon nitride film, a high dielectric film such as an aluminum oxide film or a hafnium oxide film, or a stacked structure of a low dielectric film such as a silicon oxide film or a silicon nitride film and the high dielectric film with a thickness of about 10 nm may be used. As the control gate electrode films 24, for example polycrystalline silicon films with a thickness of 45 nm or so and with which N type impurities such as P, As and the like are doped may be used.

In the capacitor region R_{C}, a silicon oxide film and the like with a thickness of 6 to 10 nm or so may be used as the first insulating film 13c. As the first electrode film 14c, for example a polycrystalline silicon film and the like with a thickness of 80 nm or so and with which N type impurities such as P, As and the like are doped may be used. As the second insulating film 15c, for example an SiN film with a thickness of 30 nm or so may be used. As the second electrode film 16c, a polycrystalline silicon film with a thickness of 60 nm or so and with which P type impurities such as B are doped may be used. As the third insulating film 23c, a silicon oxide film, a silicon nitride film, an ONO film having a stacked structure of the silicon oxide film and the silicon nitride film, a high dielectric film such as an aluminum oxide film and a hafnium oxide film, or a stacked structure of a low dielectric film such as a silicon oxide film or a silicon nitride film and the high dielectric film with a thickness of about 10 nm may be used. As the third electrode film 24c, for example a polycrystalline silicon film with a thickness of 45 nm or so and with which N type impurities such as P, As and the like are doped may be used. As the element isolation insulating films 22, silicon oxide films and the like may be used.

Further, as the metal electrode film 25, for example a W film with a thickness of 50 nm or so may be used, and as the first contact 31 and the second contact 32, W or Al may be used.

In the capacitor C of the embodiment, the first electrode film 14c and the third electrode film 24c configured of the N type semiconductor films as described above are connected via the first contact 31 so as to have the same potential, and the P type semiconductor substrate 11 and the second electrode film 16c configured of the P type semiconductor film are connected via the second contact 32 so as to have the same potential.

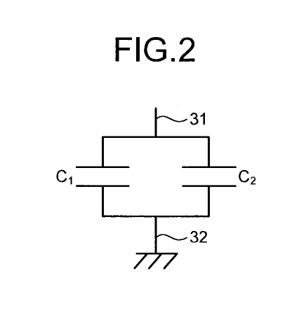

FIG. 2 is one example of an equivalent circuit diagram of the capacitor of the embodiment. In a case where the first contact 31 is set at a positive potential, and the second contact 32 is set at a ground potential (GND), a structure in which a capacitor C₁ having a structure of intervening the second insulating film 15c between the first electrode film 14c and the second electrode film 16c and a capacitor C₂ having a structure of intervening the third insulating film 23c between the second electrode film 16c and the third electrode film 24c are connected in parallel is formed. As a result, the capacitance C between the first contact 31 and the second contact 32 becomes as in the following equation (1).

C=C₁+C₂ (1)

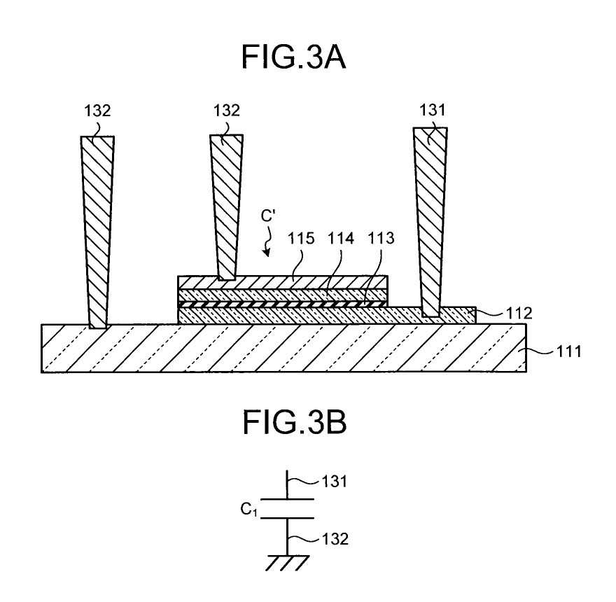

FIG. 3A is a cross sectional view illustrating a structure of a capacitor provided in comparative of a nonvolatile semiconductor memory device, and FIG. 3B is an equivalent circuit diagram of the capacitor of FIG. 3A. As illustrate in FIG. 3A, a capacitor C′ of the nonvolatile semiconductor memory device has a structure in which a first electrode film 112, a second insulating film 113, a second electrode film 114, and a metal electrode film 115 are stacked above a region divided by an element isolation insulating film that is not illustrated of a semiconductor substrate 111. Further, a first contact 131 is connected to the first electrode film 112 by penetrating an interlayer insulating film that is not illustrated, and a second contact 132 is connected to the semiconductor substrate 111 and the metal electrode film 115 by penetrating the interlayer insulating film that is not illustrated so that the semiconductor substrate 111 and the metal electrode film 115 (second electrode film 114) come to be at a same potential.

Here, the first electrode film 112 is configured of a same material as a floating gate electrode film of a memory cell transistor that is not illustrated, and gate electrode films of a low electric field transistor LVT and a high electric field transistor HVT, the second insulating film 113 is configured of a same material as an inter-electrode insulating film of the memory cell transistor, and the second electrode film 114 is configured of a same material as a control gate electrode film of the memory cell transistor.

In a case where the first contact 131 is set at the positive potential, and the second contact 132 is set at the ground potential (GND), a capacitor C₁ having a structure of intervening the second insulating film 113 between the first electrode film 112 and the second electrode film 114 is formed. That is, a capacitance C′ between the first contact 131 and the second contact 132 becomes as in the following equation (2).

C=C₁ (2)

As a result, in the capacitor of this embodiment, compared to the comparative case, the capacitance increases by the amount of C₂ (the amount of the capacitance of the second insulating film 15c between the first electrode film 14c and the second electrode film 16c). Due to this, the capacitance can be increased compared to the comparative case without enlarging the layout area of the capacitance section and further, without thinning the film thickness of the inter-electrode insulating film 23 (third insulating film 23c).

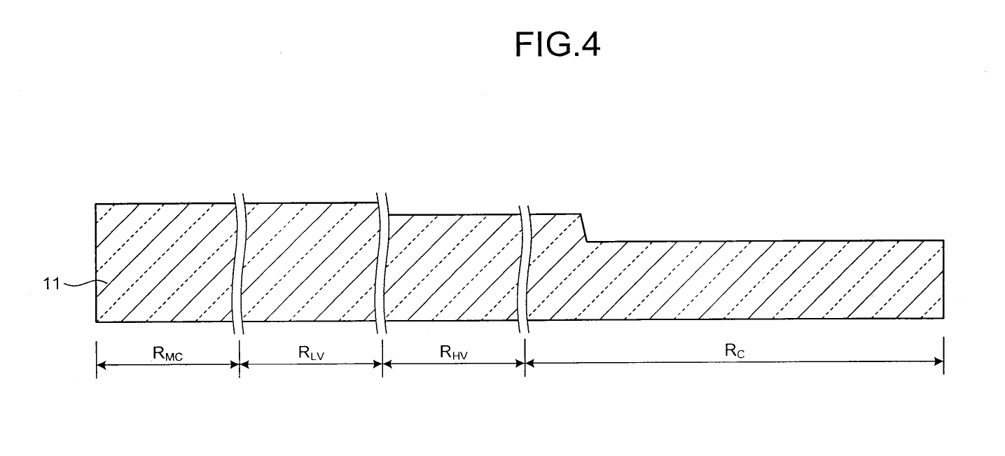

Next, one example of a manufacturing method of the nonvolatile semiconductor memory device having such a structure will be described. FIG. 4 to FIG. 21 are diagrams illustrating an example of a procedure of the manufacturing method of the nonvolatile semiconductor memory device of the embodiment.

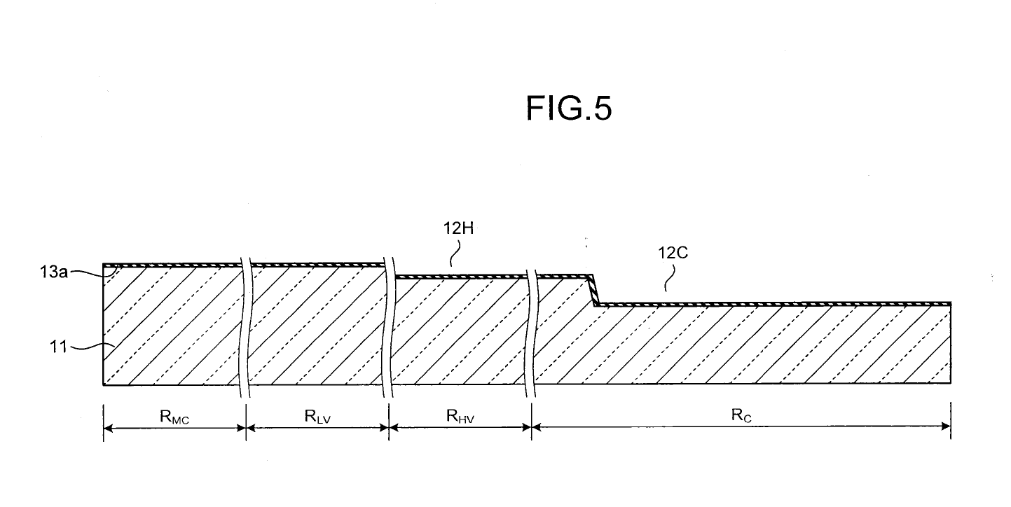

Firstly, as illustrated in FIG. 4, the semiconductor substrate 11 with which P type impurities are doped, such as a P type silicon substrate, is prepared. Next, as illustrated in FIG. 5, etching process is performed so that the surface of the semiconductor substrate 11 in the HVT region R_{HV} and the capacitor region R_{C} becomes lowered by the predetermined amounts relative to the surfaces of the memory cell region R_{MC} and the LVT region R_{LV}. For example, a mask is formed in the memory cell region R_{MC}, the LVT region R_{LV}, the HVT region R_{HV}, and a region where the second contact are formed, and a trench 12C with a first depth is formed in the capacitor region R_{C} by an anisotropic etching such as a RIE (Reactive Ion Etching) method. Thereafter, a mask is formed in the memory cell region R_{MC}, the LVT region R_{LV}, and the capacitor region R_{C}, and a trench 12H with a second depth is formed in a region where the HVT region R_{HV} and the second contact are to be formed by the anisotropic etching such as the RIE method. Notably, the first depth of the trench 12C is formed deeper than the second depth of the trench 12H. Further, the first depth and the second depth are determined so that the positions of the upper surfaces of the metal electrode films 25 of the low electric field transistor LVT, the high electric field transistor HVT, and the capacitor C to be formed finally match one another. Further, the step is formed in the semiconductor substrate 11 between the capacitor C and the second contact 32.

Next, an insulating film 13a that is a sacrificial oxide film for impurity injection such as well, channel and the like is formed on the upper surface of the semiconductor substrate 11 on which the trenches 12C, 12H are formed. The insulating film 13a can be formed for example by thermal oxidation. After the impurity injecting step is completed, the insulating film 13a is removed by etching using a wet process.

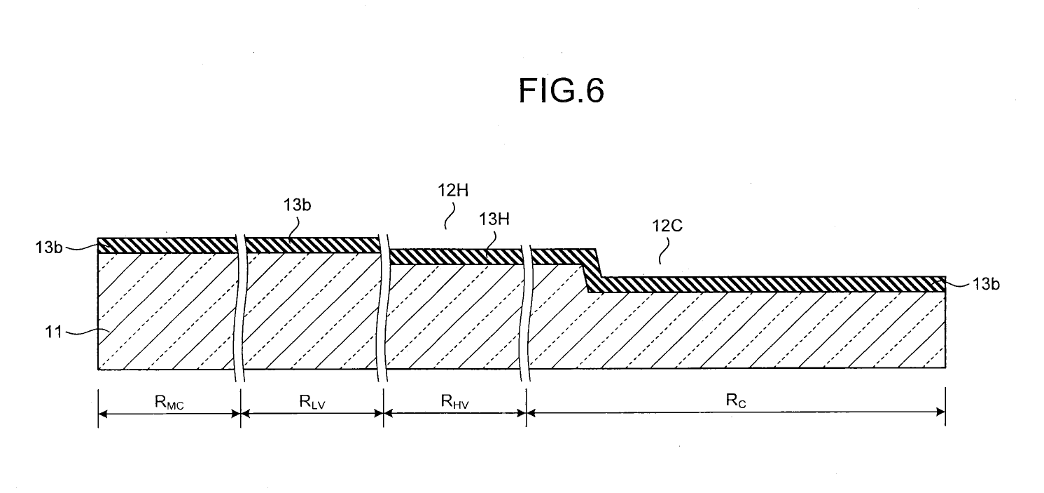

Thereafter, as illustrated in FIG. 6, an oxidation process is performed on the surface of the semiconductor substrate 11 so as to form a new insulating film 13b. The insulating film 13b formed in the HVT region R_{HV} becomes the gate insulating film 13H of the high electric field transistor HVT. Here, the oxidation process is performed so that the insulating film 13b comes to have a thickness of 40 nm or so.

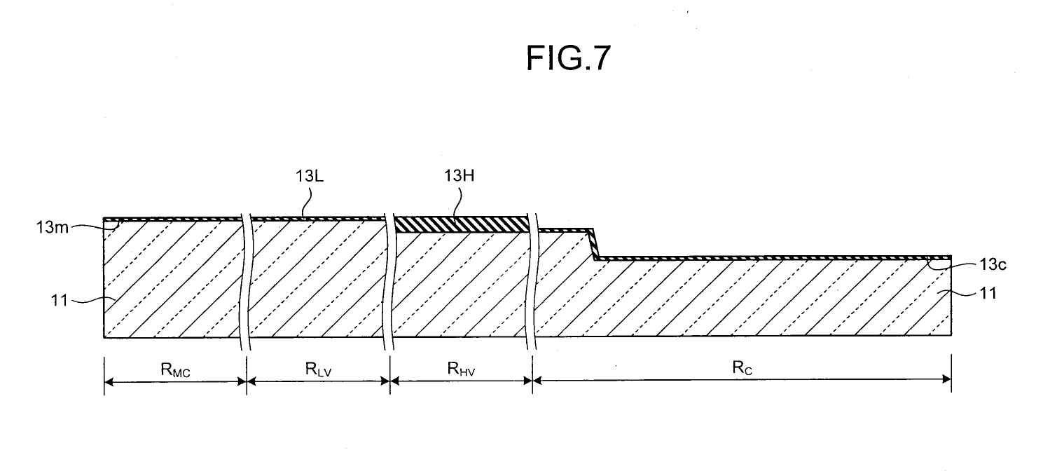

Next, as illustrated in FIG. 7, a mask that is not illustrated is formed in the HVT region R_{HV}, and the insulating film 13b formed above the memory cell region R_{MC}, the LVT region R_{LV}, and the capacitor region R_{C} is entirely removed by isotropic etching by a wet process. Thereafter, an oxidation process is performed on the surface of the semiconductor substrate 11 so as to form a new insulating film with a thickness of 8 nm or so. Due to this, a tunnel insulating film 13m is formed in the memory cell region R_{MC}, a gate insulating film 13L is formed in the LVT region R_{LV}, and a first insulating film 13c is formed in the capacitor region R_{C}.

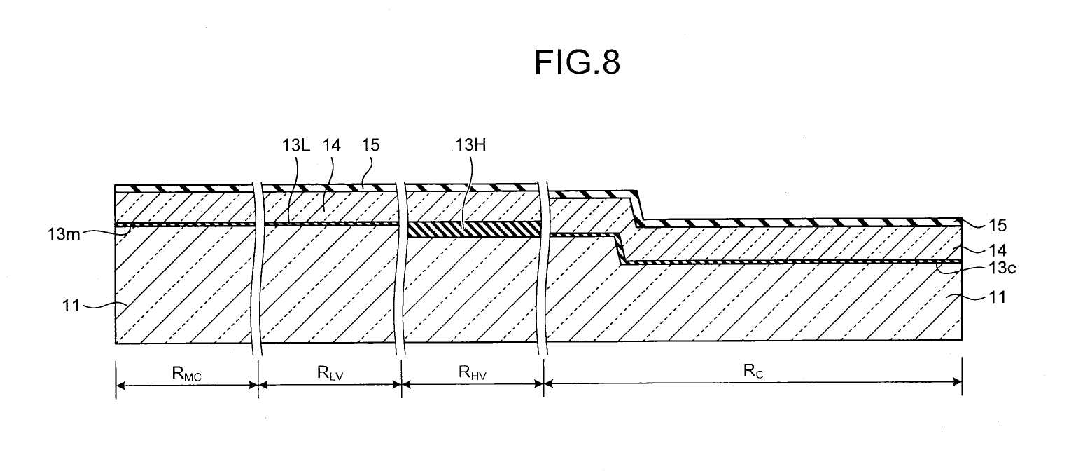

Thereafter, as illustrated in FIG. 8, a semiconductor film 14 to which N type impurities are injected and a pad insulating film 15 are orderly stacked above the semiconductor substrate 11. The semiconductor film 14 is a film configuring a part of the gate electrodes in the low electric field transistor LVT and the high electric field transistor HVT, and a polycrystalline silicon film with a thickness of 80 nm or so and having the N type impurities such as P, As and the like impurities may be used, for example. Further, the pad insulating film 15 is a film as a stopper upon etching a film formed above the pad insulating film 15 in the LVT region R_{LV} and the HVT region R_{HV} in a later step, and for example a SiN film with a thickness of 30 nm or so may be used. Notably, the pad insulating film 15 is a component that also configures a second insulating film in the capacitor C.

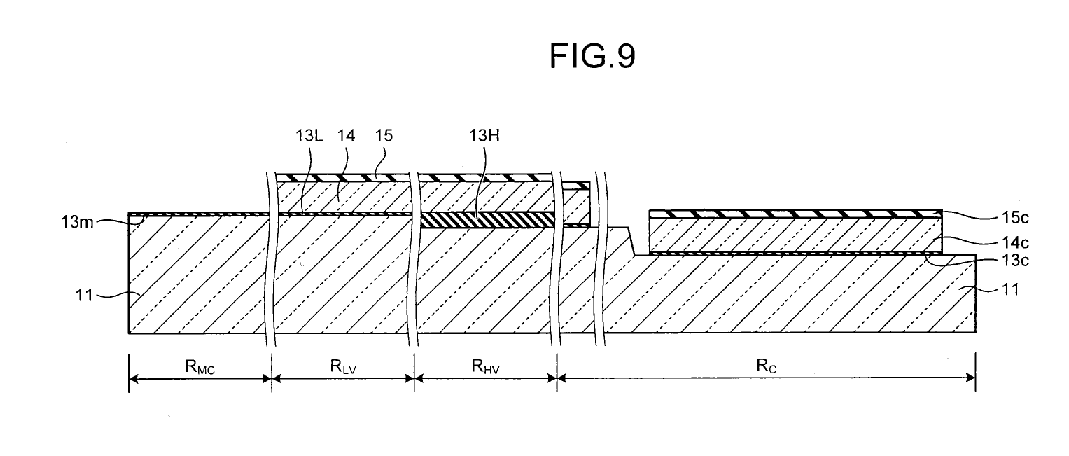

Next, as illustrated in FIG. 9, a resist that is not illustrated is applied above the pad insulating film 15, and a resist pattern that covers the LVT region R_{LV}, the HVT region R_{HV}, the capacitor region R_{C}, and the region where the second contact are formed is formed by a lithography technique. Here, it is preferable not to cover the step portion between the first electrode film 14c and the second contact 32 in the capacitor C by the resist pattern. Thereafter, the pad insulating film 15 and the semiconductor film 14 in the memory cell region R_{MC} are etched with the resist pattern as a mask by using the etching technique such as the RIE method. Due to this, in the memory cell region R_{MC}, the tunnel insulating film 13m is exposed.

Further, a resist that is not illustrated is applied above the tunnel insulating film 13m and the pad insulating film 15, and a resist pattern covered a region where the memory cell region R_{MC}, the LVT region R_{LV}, the HVT region R_{HV}, and the capacitor C in the capacitor region R_{C} are formed is formed by the lithography technique. Thereafter, the pad insulating film 15, the semiconductor film 14 and the first insulating film 13c in the capacitor region R_{C} are etched with the resist pattern as a mask by using the etching technique such as the RIE method. Due to this, the semiconductor substrate 11 is exposed in the region in the capacitor region R_{C} that is not covered by the resist pattern. Further, the semiconductor film 14 in the capacitor region R_{C} becomes the first electrode film 14c, and the pad insulating film 15 becomes the second insulating film 15c.

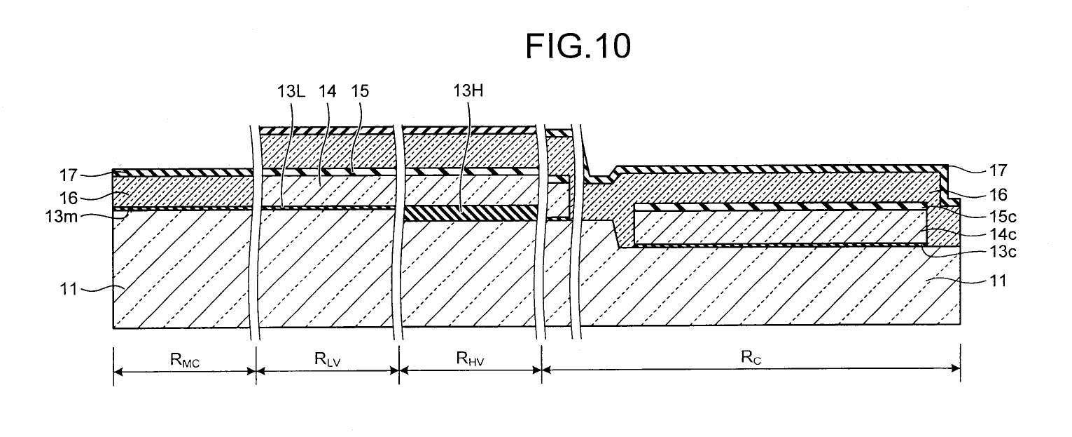

Thereafter, as illustrated in FIG. 10, a semiconductor film 16 with which P type impurities are doped and a pad insulating film 17 are formed above the semiconductor substrate 11. A polycrystalline silicon film with a thickness of 60 nm or so and having P type impurities such as Boron may be used as the semiconductor film 16, for example. The pad insulating film 17 is a film as a stopper upon etching a film formed above the memory cell region R_{MC}, the LVT region R_{LV}, the HVT region R_{HV}, and the capacitor region R_{C} in a later step, and for example a SiN film with a thickness of 30 nm or so may be used.

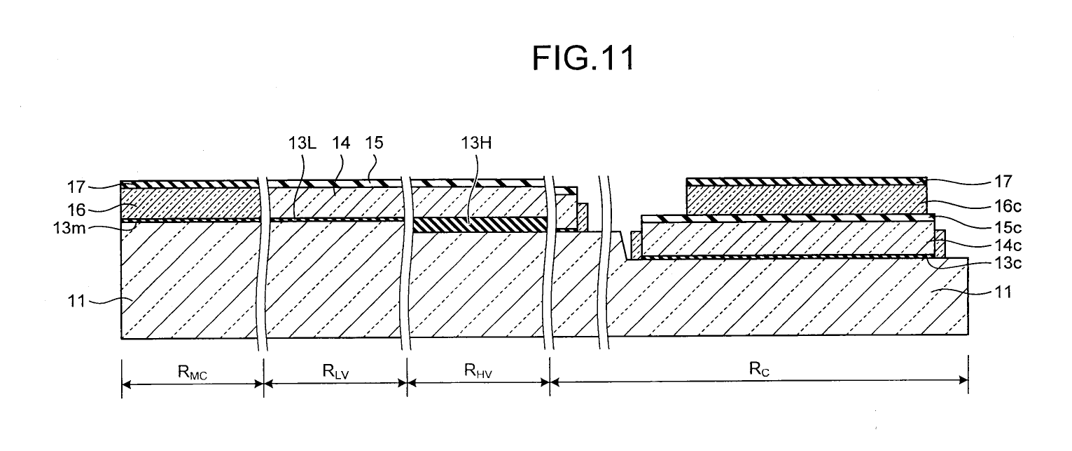

Next, as illustrated in FIG. 11, a resist that is not illustrated is applied above the pad insulating film 17, and a resist pattern covered the memory cell region R_{MC}, and a part of the capacitor region R_{C} is formed by the lithography technique. At this occasion, in the capacitor region R_{C}, within the stacked body of the first electrode film 14c and the second insulating film 15c, a region with a smaller area than an area of the stacked body is covered by the resist pattern in a view of an upper side of the stacked body. Thereafter, the pad insulating film 17 and the semiconductor film 16 are etched by using the resist pattern as a mask using the etching technique such as the RIE method. Due to this, the pad insulating film 15 is exposed in the LVT region R_{LV} and the HVT region R_{HV}. Further, the pad insulating film 15 and the semiconductor substrate 11 are exposed at a part of the capacitor region R_{C}, and the semiconductor film 16 above the stacked body becomes the second electrode film 16c.

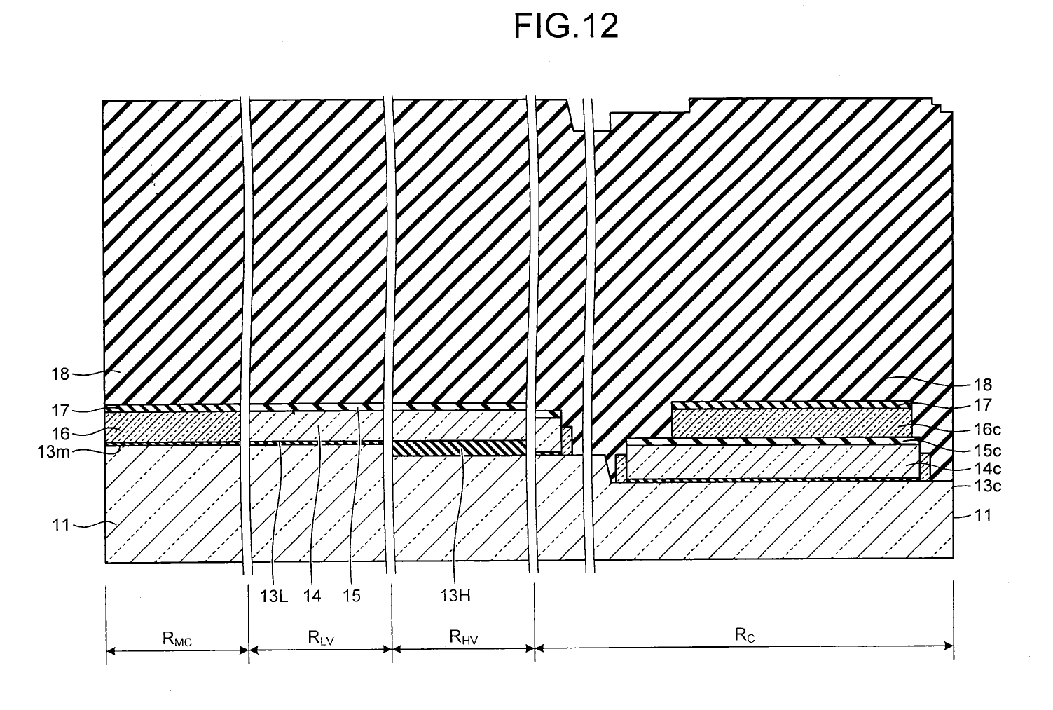

Next, as illustrated in FIG. 12, a mask film 18 for forming a trench for an element isolation insulating film is formed in the memory cell region R_{MC} above the semiconductor substrate 11. As the mask film 18, a silicon oxide film, a silicon nitride film and the like may be used.

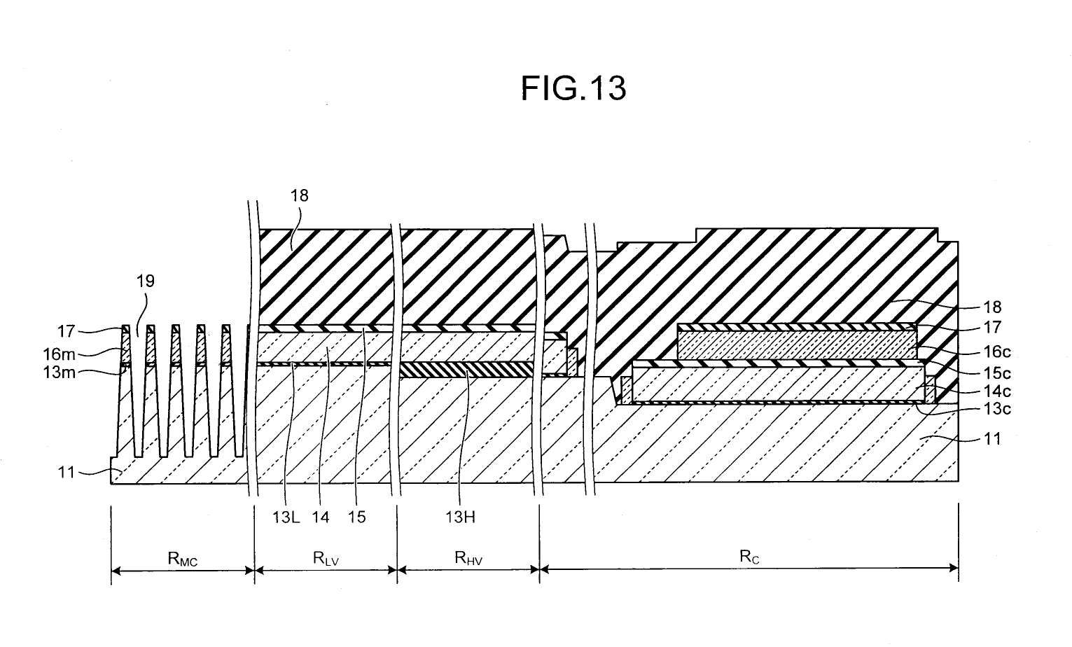

Thereafter, as illustrated in FIG. 13, a resist pattern that is not illustrated for forming a trench 19 for the element isolation insulating film is formed above the mask film 18, and the resist pattern is transferred above the mask film 18. Further, etching is performed from the pad insulating film 17 in the memory cell region R_{MC} to a predetermined depth in the semiconductor substrate 11 by using the pattern formed on the mask film 18 as a mask using the anisotropic etching technique such as the RIE method. Due to this, the trench 19 for the element isolation insulating film is formed. Further, due to the above, the semiconductor film 16 becomes the floating gate electrode films 16m.

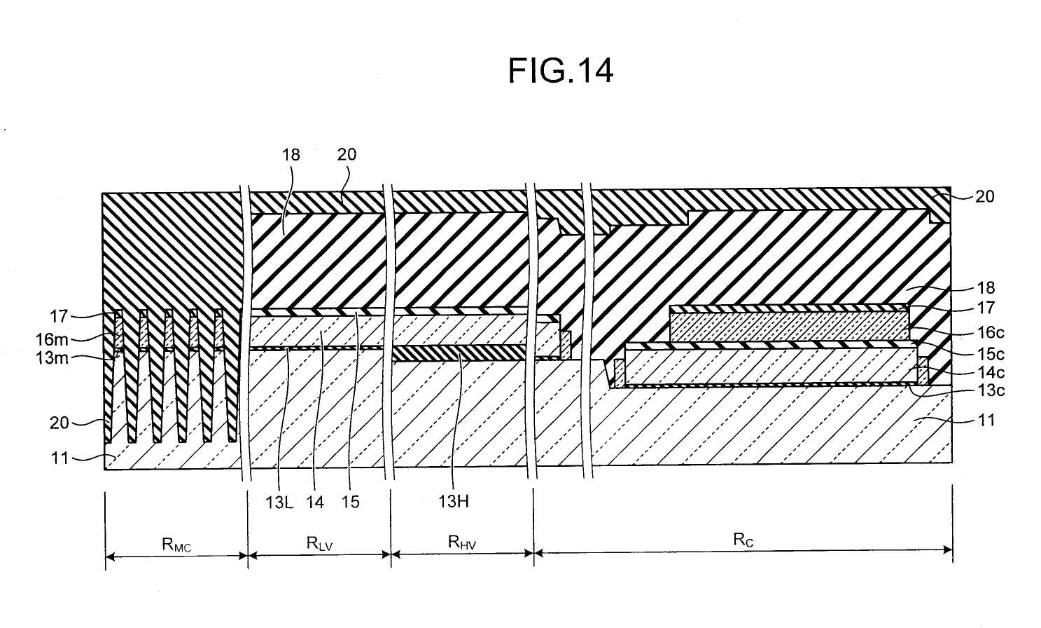

Next, as illustrated in FIG. 14, an element isolation insulating film 20 is formed in the trench 19 for the element isolation insulating film so as to be embedded therein. An upper surface of the element isolation insulating film 20 is formed to be higher than the upper surface of the mask film 18 formed in the LVT region R_{LV}, the HVT region R_{HV}, and the capacitor region R_{C}. As the element isolation insulating film 20 is formed of polysilazane and the like.

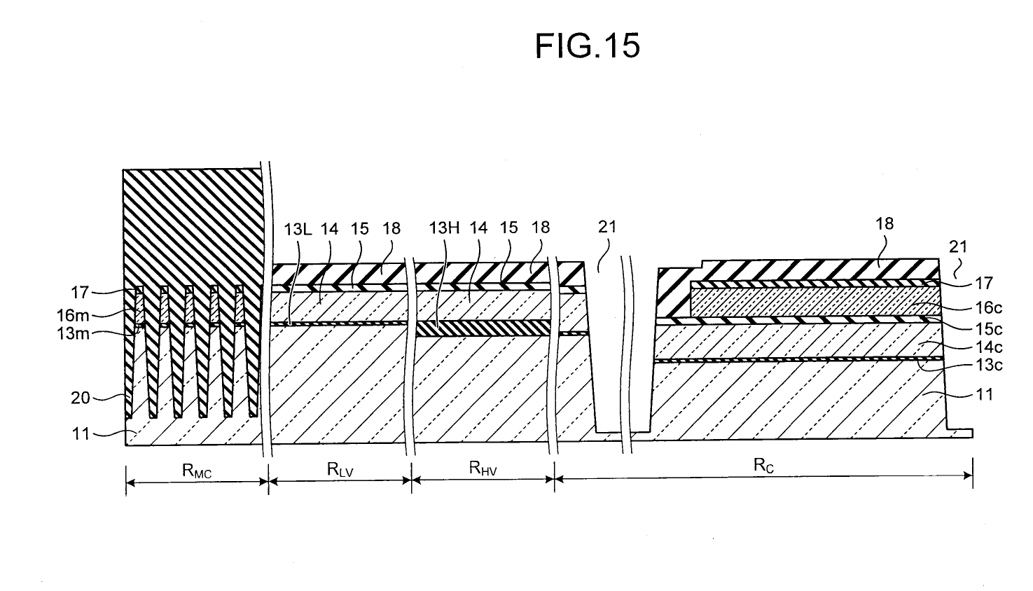

Thereafter, as illustrated in FIG. 15, a resist that is not illustrated is applied above the semiconductor substrate 11, and a resist pattern for forming trenches 21 for element isolation insulating film is formed in the LVT region R_{LV}, the HVT region R_{HV}, and the capacitor region R_{C}. Subsequently, by using the anisotropic etching technique such as the RIE method, etching is performed from the element isolation insulating film 20 in the LVT region R_{LV}, the HVT region R_{HV}, and the capacitor region R_{C} to a predetermined depth of the semiconductor substrate 11. Due to this, the trenches 21 for element isolation insulating film are formed. Notably, the trenches 21 for element isolation insulating film in the LVT region R_{LV} and the HVT region R_{HV} are not illustrated. At this occasion, in the capacitor region R_{C}, the second electrode film 16c that had been formed on a side surface of the first electrode film 14c and a side surface of the second electrode 14 in the region where the second contact is to be formed is removed.

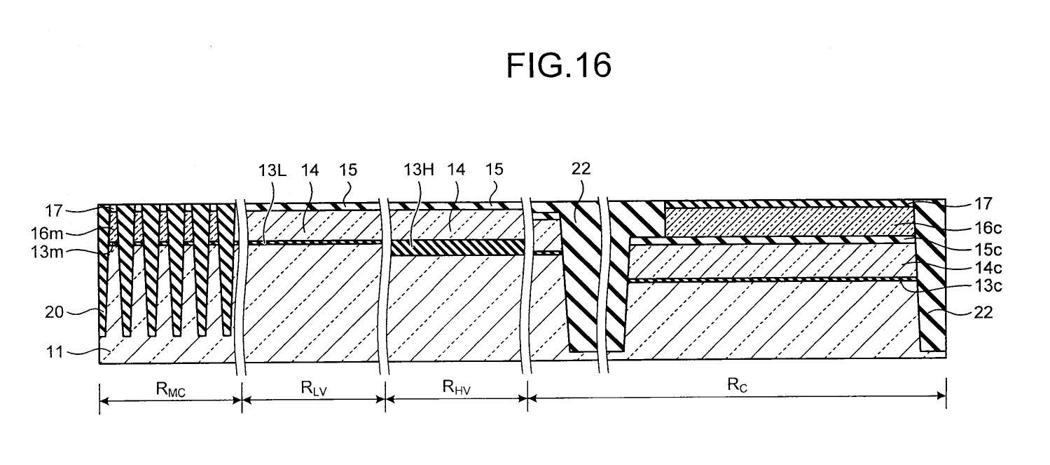

Next, as illustrated in FIG. 16, planarizing is performed by removing a layer formed above the pad insulating films 15, 17 using the pad insulating films 15, 17 as the stoppers by using a CMP (Chemical Mechanical Polishing) method. Due to this, an element isolation insulating film 22 is formed in each trench 21 for element isolation insulating film.

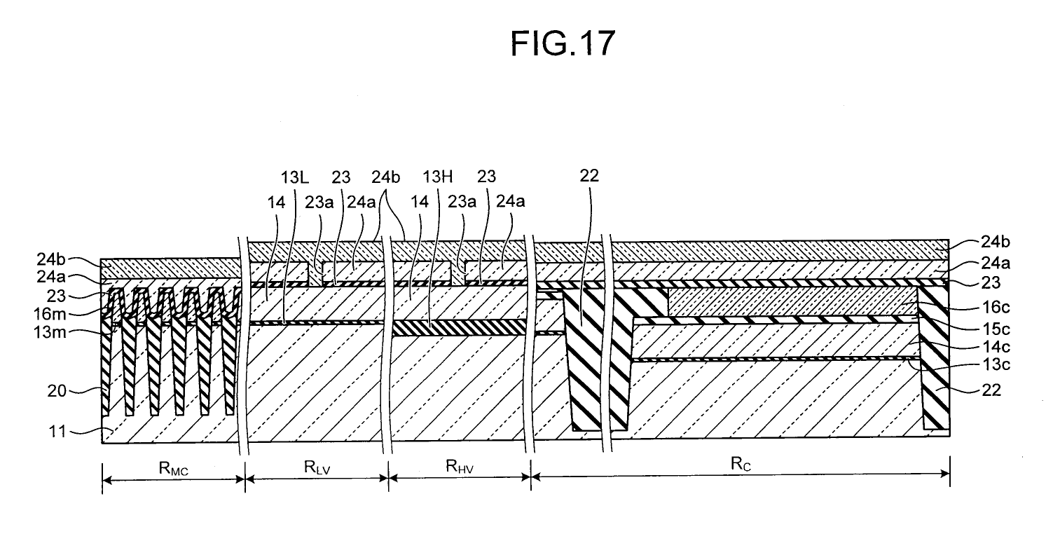

Thereafter, as illustrated in FIG. 17, the element isolation insulating film 20 in the memory cell region R_{MC} is selectively etched by an etching method such as a wet etching process. At this occasion, etching time is controlled so that upper surfaces of the element isolation insulating films 20 are positioned between the upper surfaces of the tunnel insulating films 13m and the upper surfaces of the floating gate electrode films 16m. Due to this, trenches extending in the extended direction of the element isolation insulating films 20 are formed above the element isolation insulating films 20, and the structure in which each floating gate electrode film 16m is projected between adjacent element isolation insulating films 20 is formed. Subsequently, the pad insulating films 15, 17 above the semiconductor substrate 11 are removed by etching such as the RIE method.

Next, the inter-electrode insulating film 23 is formed above the semiconductor substrate 11. In the memory cell region R_{MC}, the inter-electrode insulating film 23 is formed so that the floating gate electrode films 16m with the projected structure are covered conformally. As the inter-electrode insulating film 23, for example a silicon oxide film or a silicon nitride film with a thickness of 10 nm may be used.

Further, the control gate electrode film 24a is formed on the inter-electrode insulating film 23. As the control gate electrode film 24a, for example a polycrystalline silicon film with a thickness of 20 nm or so and having P type impurities such as Boron may be used. Thereafter, in semiconductor film 14 forming regions in the LVT region R_{LV} and the HVT region R_{HV}, the openings 23a penetrating the inter-electrode insulating film 23 and the control gate electrode film 24a in the thickness direction are formed by using the lithography technique and the etching technique.

Next, on the control gate electrode film 24a, the control gate electrode film 24b configured of an intrinsic semiconductor film with which no impurity is doped is formed. The control gate electrode film 24b is formed so as to embed in the openings 23a formed in the control gate electrode film 24a and the inter-electrode insulating film 23 in the LVT region R_{LV} and the HVT region R_{HV}. Due to this, the semiconductor film 14 and the control gate electrode films 24a, 24b are physically connected in the LVT region R_{LV} and the HVT region R_{HV}.

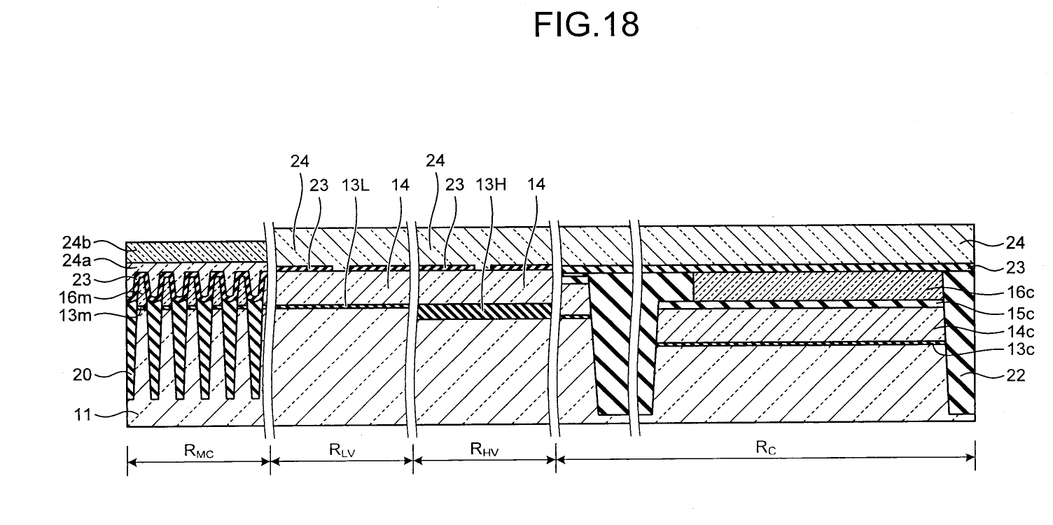

Thereafter, as illustrated in FIG. 18, N type impurities such as Phosphorus, Arsenic and the like are doped only with the control gate electrode films 24a, 24b in the peripheral circuit region by an ion injection method and the like, and activation is performed by thermal treatment. Due to this, the control gate electrode film 24 is formed by the control gate electrode films 24a, 24b in the peripheral circuit region. Notably, in the memory cell region R_{MC}, since no impurity is injected in the control gate electrode film 24b, it does not become n type.

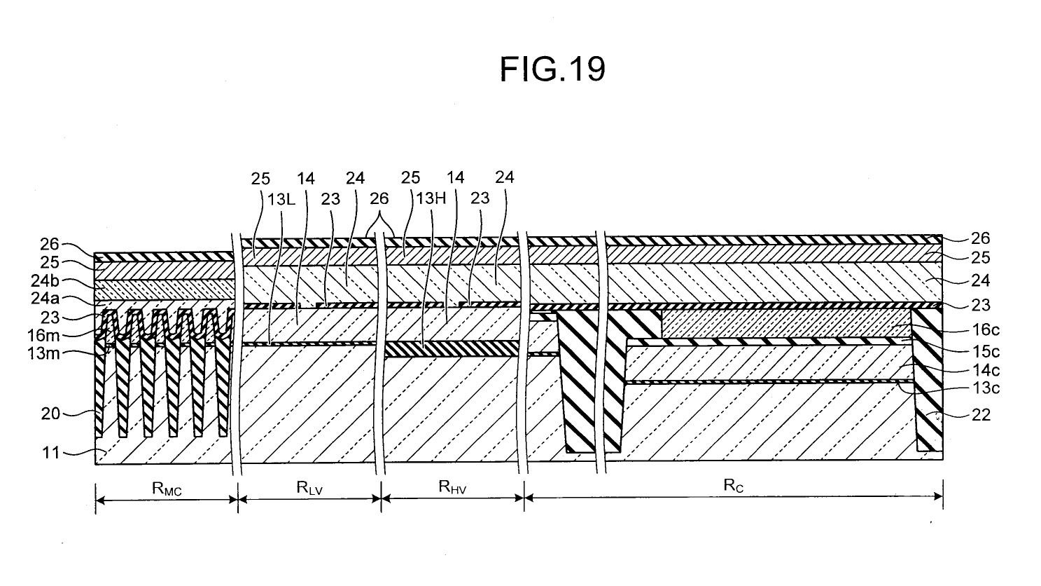

Next, as illustrated in FIG. 19, the metal electrode film 25 and a cap film 26 are formed above an entire surface of the semiconductor substrate 11. As the metal electrode film 25, for example a W film may be used, and as the cap film 26, for example a SiN film may be used.

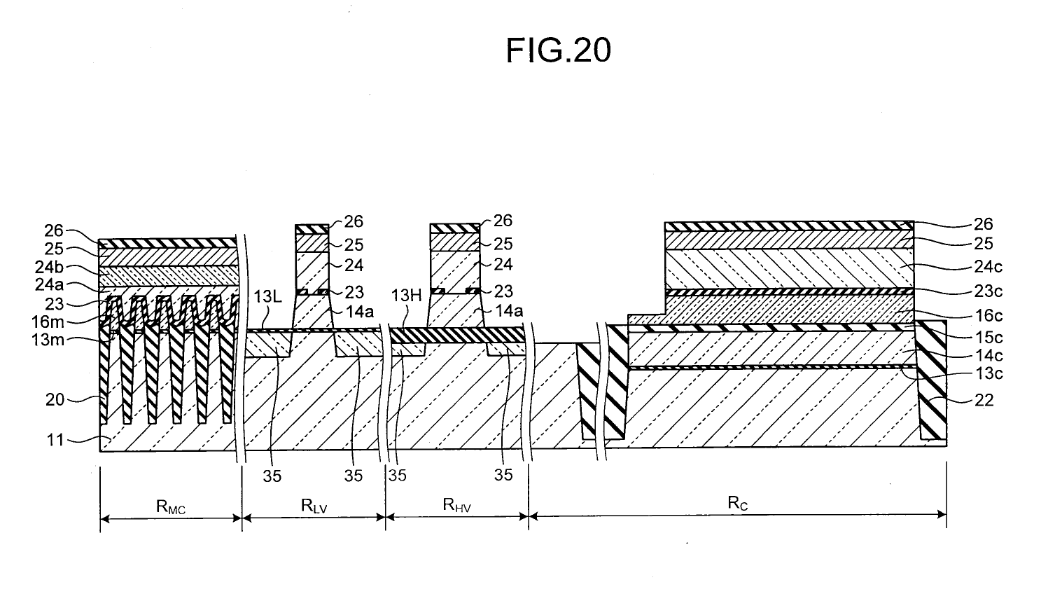

Thereafter, as illustrated in FIG. 20, in the memory cell region R_{MC}, etching is performed on the metal electrode film 25 to the floating gate electrode films 16m in a line-and-space shape extending in a direction intersecting the extended direction of the element isolation insulating films 20. Further, in the LVT region R_{LV} and the HVT region R_{HV}, etching is performed from the cap film 26 to the gate electrode film 14. Due to this, in the LVT region R_{LV} and the HVT region R_{HV}, the semiconductor film 14 becomes the gate electrode films 14a. As a result, in the LVT region R_{LV}, the gate structure in which the gate electrode film 14a, the inter-electrode insulating film 23, the control gate electrode film 24, and the metal electrode film 25 are stacked above the gate insulating film 13L is formed, and in the HVT region R_{HV}, the gate structure in which the gate electrode film 14a, the inter-electrode insulating film 23, the control gate electrode film 24, and the metal electrode film 25 are stacked above the gate insulating film 13H is formed.

Further, at the same time, in the capacitor region R_{C}, etching is performed from the cap film 26 to a middle of the gate electrode film 14 so that the capacitor C comes to have a desired shape. Due to this, the inter-electrode insulating film 23 becomes the third insulating film 23c, and the control gate electrode film 24 becomes the third electrode film 24c. Further, the second electrode 14 and the gate insulating film 13L in the region where the second contact is to be formed are removed. Further, the upper surface of the element isolation insulating film 22 adjacent to the gate electrode film 14 can be made lower than the surface of the semiconductor substrate 11 in the capacitor region R_{C}.

Moreover, in the memory cell region R_{MC}, the stacked gate structure in which the floating gate electrode film 16m, the inter-electrode insulating film 23, the control gate electrode film 24a, the control gate electrode film 24b, and the metal electrode film 25 are stacked is formed above each tunnel insulating film 13m.

Thereafter, the source/drain regions 35 are formed by diffusing impurities of a predetermined conductivity type by the ion injection method to the surfaces of the semiconductor substrate 11 on both sides in a gate longitudinal direction of the stacked gate structure and the gate structure with the stacked gate structure of the memory cell region R_{MC} and the gate structures of the LVT region R_{LV} and the HVT region R_{HV} as a mask.

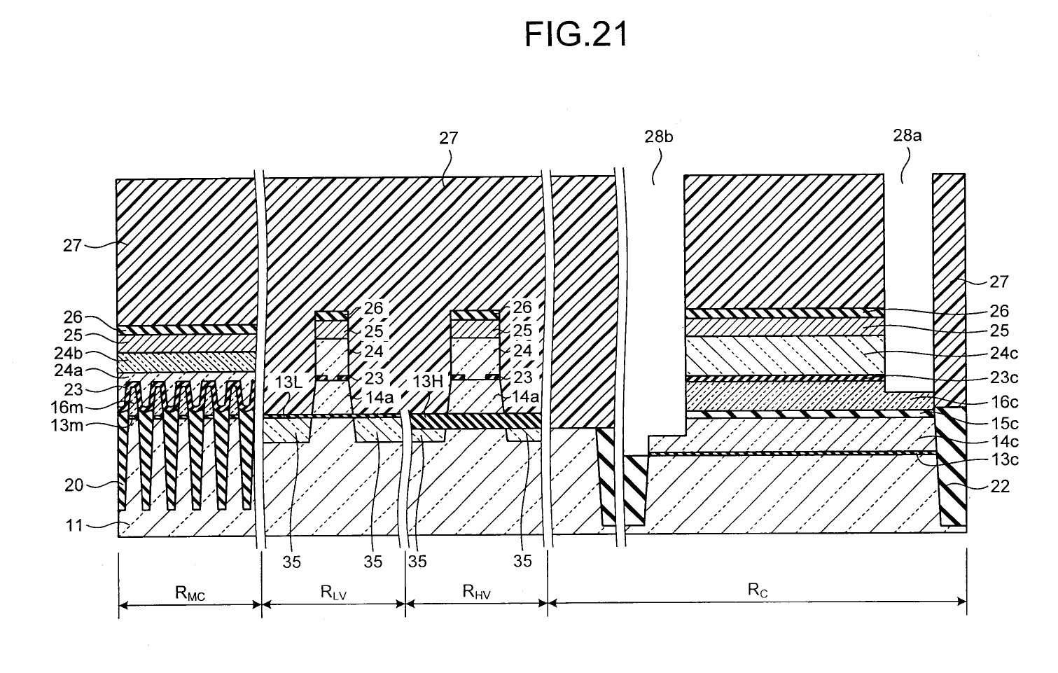

Then, as illustrated in FIG. 21, a resist is applied above the semiconductor substrate 11, and a resist pattern 27 having contact formation areas 28a, 28b opened by the lithography technique is formed in the capacitor region R_{C}. Thereafter, etching is performed by using the anisotropic etching technique such as the RIE method. Due to this, in the capacitor region R_{C}, the contact formation area 28a in which etching is performed from the cap film 26 to a middle of the second electrode film 16c and the contact formation area 28b in which etching is performed from a middle of the second electrode film 16c to a midst of the first electrode film 14c are formed.

After having removed the resist, the cap film 26 is removed by the etching technique such as the RIE method. Then, an interlayer insulating film is formed above the entire surface of the semiconductor substrate 11. As the interlayer insulating film, for example a silicon oxide film and the like may be used. Thereafter, a resist is applied onto the interlayer insulating film, and a resist pattern is formed so as to open the contact regions of the capacitor region R_{C}. The contact regions are positions where the first contact 31 and the second contact 32 are to be formed as illustrated in FIG. 1, and include the contact formation areas 28a, 28b. Thereafter, the interlayer insulating film is etched by using the etching technique such as the RIE method with the resist pattern as a mask. Due to this, the contact holes are formed.

Further, as illustrated in FIG. 1, the first contact 31 and the second contact 32 are formed by embedding a conductive material in the contact holes formed in the contact formation areas 28a, 28b. As the first contact 31 and the second contact 32, for example W may be used. According to the above, the nonvolatile semiconductor memory device of the embodiment is obtained.

Notably, in the above description, the case in which the low electric field transistor LVT and the high electric field transistor HVT are provided in the peripheral circuit region R_{PERI} has been described, however, plural types of transistors may be provided in accordance with a strength of an electric field to be applied to the transistors. In this case, a structure in which a thickness of the gate insulating film changes according to the strength of the electric field to be applied is assumed.

Further, in the capacitor C, as illustrated in FIG. 3, one layer of electrode material is additionally stacked relative to its structure. Due to this, a difference between the upper surfaces of the metal electrode films 25 in the memory cell region R_{MC}, the LVT region R_{LV}, and the HVT region R_{HV} and the upper surface of the metal electrode film 25 in the capacitor region R_{C} is enlarged. Thus, there seems to be a need to form the contact holes in the capacitor region R_{C} and the contact holes in other regions in plural occasions. However, the step is provided on the surface of the semiconductor substrate 11 in the capacitor region R_{C} so as to be lower than the surface of the semiconductor substrate 11 in the memory cell region R_{MC}, the LVT region R_{LV}, and the HVT region R_{HV}. Further, the bottom surface of the contact to the semiconductor substrate 11 in the capacitor C is positioned at a higher position than the surface of the semiconductor substrate 11 in the region where the first electrode 14c of the capacitor C is to be formed. As a result, differences in depth among the capacitor region R_{C}, the contact region to the semiconductor substrate 11 in the capacitor region R_{C}, the memory cell region R_{MC}, and bottom portions of the contact holes of the LVT region R_{LV}, and the HVT region R_{HV} become small, whereby the contact holes of the respective regions can be formed simultaneously.

In the embodiment, in the capacitor C provided in the nonvolatile semiconductor memory device, the structure in which the first electrode film 14c, the second insulating film 15c, the second electrode film 16c, the third insulating film 23c, and the third electrode film 24c are orderly stacked above the semiconductor substrate 11 is provided, the first contact 31 for supplying the same voltage to the first electrode film 14c and the third electrode film 24c is provided, and the second contact 32 for supplying the same voltage to the semiconductor substrate 11 and the second electrode film 16c is provided. Due to this, a structure in which a capacitor configured of the first electrode film 14c, the second insulating film 15c, and the second electrode film 16c, and a capacitor configured of the second electrode film 16c, the third insulating film 23c, and the third electrode film 24c are connected in parallel is assumed, and an advantageous effect that the capacitance in the capacitor C can be increased compared to a conventional case can be achieved.

Further, the first electrode film 14c is configured of the same material as parts of the gate electrode films of the low electric field transistor LVT and the high electric field transistor HVT, the second electrode film 16c is configured of the same material as the floating gate electrode films 16m of the memory cell transistors MC, and the third electrode film 24c is configured of the same material as parts of the gate electrode films of the low electric field transistor LVT and the high electric field transistor HVT. Accordingly, it is possible to increase the capacitance value per unit area without changing the layout area of the capacitor and the thickness of the inter-electrode insulating film so as to stacking the electrode films via the insulating films in the capacitor region R_{C} by utilizing the distinctive formation of the gate electrode films and the floating gate electrode films 16m in the memory cell region R_{MC} and the peripheral circuit region R_{PERI}.

Further, by configuring the first electrode film 14c and the third electrode film 24c of the N type semiconductor materials, configuring the second electrode film 16c of the P type semiconductor material, and using as a capacitance element so as to apply a forward bias to the respective semiconductor layers via the first contact 31 and the second contact 32, whereby it is possible to suppress spread of a depletion layer, and to increase the capacitance value. Notably, it is possible to select the material of the first electrode film 14c and the material of the second electrode film 16c so long as a depletion layer is not generated when a voltage is applied to one of the electrode films.

Further, by using the trench (step) for the capacitor formation, it is possible to form the contact holes connected to the respective electrode films of the capacitor C at the same time.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a memory cell transistor having a stacked gate structure including a tunnel insulating film, a charge accumulation layer, a memory cell insulating film, and a control gate electrode film are orderly stacked above a semiconductor substrate; and
a capacitor having a first insulating film, a first electrode film, a second insulating film, a second electrode film, a third insulating film, and a third electrode film are orderly stacked above the semiconductor substrate,
wherein a material of the second electrode film is same as the charge accumulation layer of the memory cell transistor, and
the third electrode film includes a material same as the control gate electrode film of the memory cell transistor.

2. The nonvolatile semiconductor memory device according to claim 1, further comprising a peripheral transistor having a gate insulating film and a gate electrode film above the semiconductor substrate,
wherein the gate electrode film includes a first semiconductor film formed above the gate insulating film, and a second semiconductor film formed above the first semiconductor film, and
a material of the first electrode film is same as the first semiconductor film of the peripheral transistor.

3. The nonvolatile semiconductor memory device according to claim 1, wherein a material of the third electrode film is same as the second semiconductor film of the peripheral transistor.

4. The nonvolatile semiconductor memory device according to claim 3, wherein the third electrode film and the second semiconductor film of the peripheral transistor are of a same conductive type.

5. The nonvolatile semiconductor memory device according to claim 1, wherein the charge accumulation layer includes a semiconductor layer with which impurities are doped, and the third electrode film and the semiconductor layer are of different conductive types.

6. The nonvolatile semiconductor memory device according to claim 5, wherein the control gate electrode film of the memory cell transistor includes a third semiconductor film of a first conductivity type formed above the memory cell insulating film, and a fourth semiconductor film formed above the third semiconductor film with which impurities are not doped, and
the third electrode film is a semiconductor material of a second conductivity type, the semiconductor material being made of the third semiconductor film and the fourth semiconductor film injected impurities of an opposite type from the first conductivity type.

7. The nonvolatile semiconductor memory device according to claim 1, wherein a material of the third insulating film is same as the memory cell insulating film of the memory cell transistor.

8. The nonvolatile semiconductor memory device according to claim 1, further comprising first to fourth contacts that are respectively connected to the semiconductor substrate, the first electrode film, the second electrode film, and the third electrode film,
wherein the first contact and the third contact are electrically connected, and
the second contact and the fourth contact are electrically connected.

9. The nonvolatile semiconductor memory device according to claim 8, wherein the first contact and the third contact are applied a ground potential, and
the second contact and the fourth contact are applied a positive potential.

10. The nonvolatile semiconductor memory device according to claim 9, wherein
the semiconductor substrate is a first conductivity type,
the first electrode film is a semiconductor material of a second conductivity type that is opposite to the first conductivity type,
the second electrode film is a semiconductor material of the first conductivity type, and
the third electrode film is a semiconductor material of the second conductivity type.

11. The nonvolatile semiconductor memory device according to claim 1, wherein a position on an upper surface of the semiconductor substrate in a region on which the capacitor is formed is positioned lower than a position of the upper surface of the semiconductor substrate on which the memory cell transistor is formed.

12. A method of manufacturing a nonvolatile semiconductor memory device including a memory cell transistor formed in a memory cell region, a peripheral transistor formed in a peripheral circuit region, and a capacitor formed in capacitor region, the method comprising:
forming a first insulating film above a semiconductor substrate in the peripheral circuit region;
forming a second insulating film above the semiconductor substrate in the memory cell region and the capacitor region;
orderly forming a first semiconductor film and a first pad insulating film above the semiconductor substrate in the peripheral circuit region and the capacitor region, the first semiconductor film, and the first pad insulating film as a stopper;
orderly forming a second semiconductor film and a second pad insulating film above the semiconductor substrate in the memory cell region and the capacitor region, and the second pad insulating film as a stopper;
forming an element isolation insulating film in the memory cell region, the peripheral circuit region, and the capacitor region;
removing the element isolation insulating film formed above the first pad insulating film in the peripheral circuit region and above the second pad insulating film in the memory cell region and the peripheral circuit region;
removing the first pad insulating film in the peripheral circuit region, and the second pad insulating film in the memory cell region and the peripheral circuit region;
forming a third insulating film above the semiconductor substrate;
forming a third semiconductor film above the semiconductor substrate;
injecting impurities to the third semiconductor film in the peripheral circuit region and the capacitor region, the impurities having a conductivity type that is opposite to a conductivity type of the third semiconductor film; and
patterning the memory cell transistor in the memory cell region, the peripheral transistor in the peripheral circuit region, and the capacitor in the capacitor region.

13. The method of manufacturing a nonvolatile semiconductor memory device according to claim 12, wherein
in the formation of the third semiconductor film, a fourth semiconductor film of a first conductivity type is formed above the memory cell insulating film, and then a fifth semiconductor film not including any impurities is formed above the fourth semiconductor film, and
in the injecting impurities, impurities of an opposite type of the first conductivity type are injected to the fifth semiconductor film in the peripheral circuit region and the capacitor region, and to the semiconductor film of the first conductivity type so that the third semiconductor film is to be second conductivity type.

14. The method of manufacturing a nonvolatile semiconductor memory device according to claim 12, wherein an upper surface of the semiconductor substrate in the capacitor region is recessed before the second insulating film is formed.

15. The method of manufacturing a nonvolatile semiconductor memory device according to claim 14, wherein the upper surface of the semiconductor substrate in the capacitor region is recessed so that an upper surface of the third semiconductor film of the peripheral transistor and an upper surface of the third semiconductor film of the capacitor become substantially at a same height after the patterning.

16. The method of manufacturing a nonvolatile semiconductor memory device according to claim 14, further comprising:
forming an interlayer insulating film above the semiconductor substrate after the patterning; and
forming first to fourth contact holes in the interlayer insulating film in the capacitor region, the first to fourth contact holes respectively exposing upper surfaces of the semiconductor substrate, the first semiconductor film, the second semiconductor film, and the third semiconductor film,
wherein the second contact hole and the third contact hole are formed at the same time.
